(19) United States
(12) Patent Application Publication
(10) Pub. No.: US 2010/0141347 A1
(43) Pub. Date: Jun. 10, 2010

(54) Band Selecting Method Applied to Voltage Controlled Oscillator of Phase Locked Loop Circuit and Associated Apparatus

(75) Inventors: SHUO YUAN HSIAO, Hsinchu Hsien (TW); YAO-CHI WANG, Hsinchu Hsien (TW); SHEN-CHING SUN, Hsinchu Hsien (TW); JIAN-YU DING, Hsinchu Hsien (TW)

Correspondence Address: WPAT, PC;INTELLECTUAL PROPERTY ATTORNEYS, 7225 BEVERLY ST., ANNANDALE, VA, 22003, US

(73) Assignee: MSTAR SEMICONDUCTOR, INC., Hsinchu Hsien (TW)

(21) Appl. No.: 12/485,513

(22) Filed: Jun. 16, 2009

(30) Foreign Application Priority Data
Dec. 5, 2008 (TW) 097147460

(51) Int. Cl. H03L 5/00

(52) U.S. Cl. 331/17

(57) ABSTRACT

A band selecting method applied to a voltage controlled oscillator (VCO) of a phase locked loop (PLL) and an associated method is provided. The band selecting method generates an open-loop control voltage according to a temperature signal; inputting the open-loop control voltage into the VCO; switching sequentially between a plurality of frequency bands of the VCO and generating a plurality of voltage controlled signals for the frequency bands; selecting a preferred voltage controlled signal and its corresponding frequency band as an operating band for the PLL.

### CROSS REFERENCE TO RELATED PATENT APPLICATION

This patent application is based on a Taiwan, R.O.C. patent application No. 097147460 filed on Dec. 5, 2008.

### FIELD OF THE INVENTION

The present invention relates to a phase locked loop (PLL), and more particularly, to a band selecting method applied to a voltage controlled oscillator (VCO) of a PLL circuit, and an associated apparatus.

### BACKGROUND OF THE INVENTION

Referring to FIG. 1 showing a phase locked loop (PLL), the PLL comprises a phase frequency detector 10, a charge pump 20, a loop filter 30, a voltage controlled oscillator (VCO) 40 and a frequency divider 45. A reference signal with a reference frequency F_{ref} is generated by a reference oscillator (not shown), and is inputted simultaneously into the phase frequency detector 10 along with a frequency divided signal from the frequency divider 45. The phase frequency detector 10 detects a phase and frequency difference between the reference signal and the frequency divided signal, and it then outputs a phase difference signal to the charge pump 20. The charge pump 20 then generates an output current associated with the phase difference signal to the loop filter 30 according to the amplitude of the phase difference signal. The loop filter 30 smoothes the output current and converts it into a control voltage V_{ctrl} to the VCO 40. The VCO 40, according to the control voltage V_{ctrl}, generates a voltage controlled signal having a voltage controlled frequency F_{vco}, which is then divided using the frequency divider 45 by N to generate a frequency divided signal upon receiving the voltage controlled signal, where N is an integer and F_{vco}=N*F_{ref}.

The VCO 40 typically has two types including an LC oscillator and a ring oscillator. To allow the VCO 40 with a higher adjustable frequency range, the VCO includes a varactor bank or a switched capacitance bank in which capacitance varies with the voltage applied, such that the VCO 40 is facilitated to provide a plurality of bands for adjusting the voltage controlled frequency F_{vco} of the voltage controlled signal. Refer to FIG. 2 showing a relationship diagram of a control voltage V_{ctrl} and a voltage controlled frequency F_{vco} of a conventional VCO.

With reference to FIG. 2, the control voltage V_{ctrl} of the voltage controlled signal has a linear control range, i.e., the range between V_{L} and V_{H}. When the VCO chooses to operate within the band 1, the voltage controlled frequency F_{vco} of the VCO varies between the range of F_{1L} and F_{1H}. When the VCO chooses to operate within the band 2, the voltage controlled frequency F_{vco} of the VCO varies between the range of F2L and F_{2H}. When the VCO chooses to operate within the band 3, the voltage controlled frequency F_{vco} of the VCO varies between the range of F_{3L} and F_{3H}. When the VCO chooses to operate within the band 4, the voltage controlled frequency F_{vco} of the VCO varies between the range of F_{4L} and F_{4H}. More specifically, the voltage controlled frequency F_{vco} of the VCO in FIG. 2 may get as large as from F_{1H} to F_{4L}. Therefore, it is concluded that the variable range of the voltage controlled frequency F_{vco} gets even larger as the number of bands provided by the VCO gets greater.

In order to maintain a stable voltage controlled frequency F_{vco} when operating the PLL in an environment where the ambient temperature varies drastically, the control voltage V_{ctrl} also needs to vary with the temperature variance. For example, FIGS. 3A, 3B and 3C are schematic diagrams of the control voltage V_{ctrl} and the voltage controlled frequency F_{vco} when a VCO of a same PLL operates under different temperatures T1, T2 and T3. Suppose the VCO selects the band 3 as its operating band, V_{L}=1V and V_{H}=2V, and the voltage controlled frequency F_{vco} is fixed at 4 GHz, and T1<T2<T3. From FIG. 3A showing the relationship diagram at the temperature T1, when the control voltage V_{ctrl} is at 1.5V, the voltage controlled frequency F_{vco} of the VCO may operate at 4 GHz. Note that, accompanied with increase in temperature, all bands of the VCO shifts downwards. Hence, as observed from FIG. 3B showing the relationship diagram at the temperature T2, to maintain the VCO to operate with the voltage controlled frequency F_{vco} at 4 GHz, the control voltage V_{ctrl} is automatically adjusted to 1.9V If the temperature continues to rise to the temperature T3, the control voltage V_{ctrl} shall also adaptively increase until it exceeds 2V. Meanwhile, the control voltage V_{ctrl} exceeds the linear control range, causing the PLL to unlock.

Therefore, the coarse band selection procedure of a VCO is extremely important. Coarse band selection is applied to select an appropriate band so that the control voltage V_{ctrl} of the VCO does not easily exceed from the linear control range. In general, before a PLL starts to operate, i.e., when power is switched on or a circuit is reset, the PLL starts to operate provided that the VCO undergoes coarse band selection for selecting a specific band.

Coarse selection includes closed-loop coarse selection and open-loop coarse selection. For closed-loop coarse selection, the selection of a band appears rather less important. The reason behind is that, a monitor circuit is provided for continuously monitoring the control voltage V_{ctrl} in PLL operations, and the monitor circuit changes the band of the VCO to have the control voltage V_{ctrl} return within the linear control range whenever the control voltage V_{ctrl} exceeds the linear control range.

More specifically, at the temperature 3T, the monitor circuit selects the band 2 of the VCO for operations when having detected that the control voltage V_{ctrl} exceeds the linear control range, as shown in FIG. 3C. Thus, the control voltage V_{ctrl} returns to 1.45V, that is, returns to the linear control range so that the PLL stays being locked.

However, the monitor circuit need continuously monitor the control voltage V_{ctrl}, meaning that the monitor circuit continuously consumes power—such monitor circuit is inappropriate for a PLL to monitor the control voltage V_{ctrl} in a circuit that requires low power consumption.

Further, band selection for an open-loop coarse selection procedure is performed during power on or when the circuit is reset, and the band is stays unchanged thereafter without causing the foregoing issue of continuous power consumption. Therefore, the open-loop coarse selection procedure is crucial for normal operations of the PLL, or the PLL may become unlocked if the open-loop coarse selection is not performed appropriately.

Suppose the linear control range of the PLL is between V_{L} and V_{H}, an open-loop control voltage of 1/2(V_{L}+V_{H}) is set for performing coarse band selection. Further, connection between the loop filter 30 and the VCO 40 is opened to form an open loop. Different bands of the VCO 40 are sequentially selected and the voltage inputted into the VCO 40 is controlled using the open loop to enable the VCO 40 to output voltage controlled output signals corresponding to different voltage controlled frequencies F_{vco}. The voltage controlled output signals of different voltage controlled frequencies F_{vco} using the frequency divider 45, have the voltage controlled frequencies F_{vco} divided by N to generate different frequency divided signals. All the frequencies of the frequency divided signals are compared with the reference frequency F_{ref} of the reference signal, and a band, of the VCO 40, corresponding to divided frequency signal with a frequency closest to the reference frequency F_{ref} is selected as the coarse band.

Refer to FIG. 4A showing a schematic diagram illustrating an open-loop coarse selection procedure. Suppose the VCO 40 has four bands 1, 2, 3 and 4, V_{L} is 1V, V_{H} is 2V, F_{ref} is 40 MHz, and N of the frequency divider 45 is 100. Therefore, the open-loop control voltage is 1/2(V_{L}+V_{H})=1.5V.

Four situations of four bands in FIG. 4A when the PLL is open shall be discussed below. In a first situation, after selecting the first band (1) of the VCO and inputting the open-loop control voltage, a first voltage controlled output signal in a first voltage controlled frequency F_{vco1} of 4.49 GHz is generated, and a first divided frequency F_{D1} of the first frequency divided signal is detected to be 44.9 MHz. In a second situation, after selecting the second band (2) of the VCO and inputting the open-loop control voltage, a second voltage controlled output signal in a second voltage controlled frequency F_{vco2} of 4.26 GHz is generated, and a second divided frequency F_{D2} of the second frequency divided signal is detected to be 42.6 MHz. In a third situation, after selecting the third band (3) of the VCO and inputting the open-loop control voltage, a third voltage controlled output signal in a third voltage controlled frequency F_{vco3} of 4.03 GHz is generated, and a third divided frequency F_{D3} of the third frequency divided signal is detected to be 40.3 MHz. In a fourth situation, after selecting the fourth band (4) of the VCO and inputting the open-loop control voltage, a fourth voltage controlled output signal in a fourth voltage controlled frequency F_{vco4} of 3.81 GHz is generated, and a fourth divided frequency F_{D4} of the fourth frequency divided signal is detected to be 38.1 MHz.

The third divided frequency F_{D3} of the third frequency divided signal is 40.3 MHz, which is the closest to 40 MHz of the reference frequency F_{ref}. Therefore, the PLL coarsely selects the third band (3) of the VCO for operations. Further, as shown in FIG. 4B, when the PLL is closed at the connection between the loop filter 30 and the VCO 40, the third band (3) becomes the operating band and the control voltage V_{ctrl} automatically adjusts to 1.4V such that the PLL steadily outputs a voltage controlled frequency F_{vco} in 4 GHz.

According to the prior art, coarse band selection in a closed PLL is aimed to identify a specific band so that the control voltage V_{ctrl} is maintained around a central area of the linear control range when the PLL is closed. However, the conventional coarse band selection in an open loop, when implemented to an environment where the ambient temperature varies drastically, causes the PLL to become unlocked. With reference to FIGS. 4A and 4B illustrating coarse band selection, suppose the PLL undergoes open-loop coarse band selection at a low temperature, e.g., 0° C., and completes coarse selection of the third band. It is apparent that, when the closed PLL starts to operate, in order to keep locking the PLL at 4 GHz, the control voltage V_{ctrl} gradually increases from 1.4V in response to the continual rise in temperature. As a result of being merely 0.6V from the upper boundary of the linear control range, the control voltage V_{ctrl} can easily exceed the linear control range when the PLL is at a high temperature, e.g. 100° C., such that the PLL becomes unlocked.

On the contrary, suppose the PLL undergoes open-loop coarse band selection at a high temperature, e.g., 125° C., and completes coarse selection of the third band. Again, it is apparent that, when the PLL operates at a low temperature, in order to keep locking the PLL at 4 GHz, the control voltage V_{ctrl} gradually decreases from 1.4V in response to the extreme drop in temperature. As a result of being merely 0.4V from the lower boundary of the linear control range, the control voltage V_{ctrl} can easily exceed the linear control range when the PLL is at a low temperature, e.g. 0° C., such that the PLL becomes unlocked.

### SUMMARY OF THE INVENTION

It is an objective of the invention to provide a band selecting method applied to a voltage controlled oscillator (VCO) of a phase locked loop (PLL), so that the PLL does not become unlocked when being operated in an environment where ambient operating temperature varies with a large range.

According to the present invention, a band selecting method applied to a VCO of a PLL in an open-loop. The VCO provides a plurality of frequency bands for selection. The band selecting method comprises steps of: generating an open-loop control voltage according to a temperature signal; inputting the open-loop control voltage into the VCO; switching sequentially between the frequency bands of the VCO so that the VCO sequentially generates a plurality of voltage controlled signal having different voltage controlled frequencies; and selecting one of the plurality of bands as an initial band so as to provide the corresponding voltage controlled voltage for the PLL in a closed-loop.

According to the present invention, a PLL comprises a loop filter, for outputting a first control voltage; an open-loop control voltage generator, for outputting a second control voltage associated with an ambient temperature; a selector, e.g., a multiplexer or a switch, for selecting either the first control voltage or the second control voltage to output as a third control voltage according to an open-loop control signal; a VCO, for generating a voltage controlled output signal according to the third control voltage; a frequency divider, for receiving the voltage controlled output signal and dividing the same to generate a frequency divided signal; a phase frequency detector, for generating a phase difference signal according to the frequency divided signal and a reference signal; a charge pump, for generating an output current to the loop filter according to the phase difference signal to generate the first control voltage; a frequency comparator, for generating a frequency difference signal according to the frequency divided signal and the reference signal; and a band selector, for switching between a plurality of frequency bands of the VCO when an open-loop control signal is asserted to further select an operating band from the bands of the VCO according to a plurality of frequency difference signals outputted by the frequency comparator, and for controlling the VCO when the open-loop control signal is deasserted to generate the voltage controlled output signal according to the operating band and the third control voltage. For example, the open-loop control voltage generator comprises a temperature detecting circuit for providing a temperature signal to associate the second control voltage with the temperature signal. Alternatively, the temperature detecting circuit is a proportional-to-absolute-temperature (PTAT) current generating circuit, and the temperature signal is a current signal generated by the PTAT current generating circuit. Alternatively, the temperature detecting circuit is a PTAT current generating circuit, and the temperature signal is generated by flowing a PTAT current through a resistor.

### BRIEF DESCRIPTION OF THE DRAWINGS

The present invention will become more readily apparent to those ordinarily skilled in the art after reviewing the following detailed description and accompanying drawings, in which:

FIG. 1 is a schematic diagram of a phase locked loop (PLL).

FIG. 2 is a relationship diagram of a control voltage V_{ctrl} and a voltage controlled frequency F_{vco} of a conventional VCO.

FIGS. 3A, 3B and 3C schematic diagrams of the control voltage V_{ctrl} and the voltage controlled frequency F_{vco} when a VCO of a same PLL operates under different temperatures T1, T2 and T3.

FIGS. 4A and 4B are schematic diagrams of a conventional coarse selection procedure.

FIG. 5 is a schematic diagram of a PTAT current generating circuit.

FIGS. 6A, 6B and 6C are schematic diagrams of a coarse selection procedure according to one preferred embodiment of the invention.

FIGS. 7A, 7B and 7C are schematic diagrams of a coarse selection procedure according to one preferred embodiment of the invention.

FIG. 8 shows a flowchart of a band selecting method applied to a VCO of a PLL according to one preferred embodiment of the invention.

FIG. 9 shows a PLL according to one preferred embodiment of the invention.

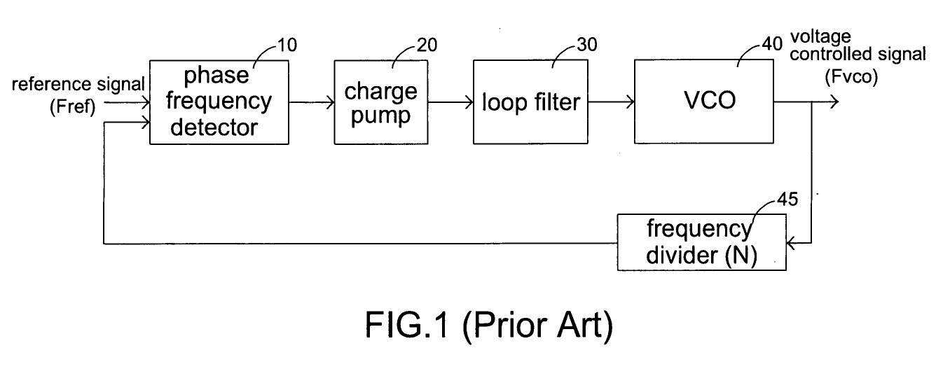

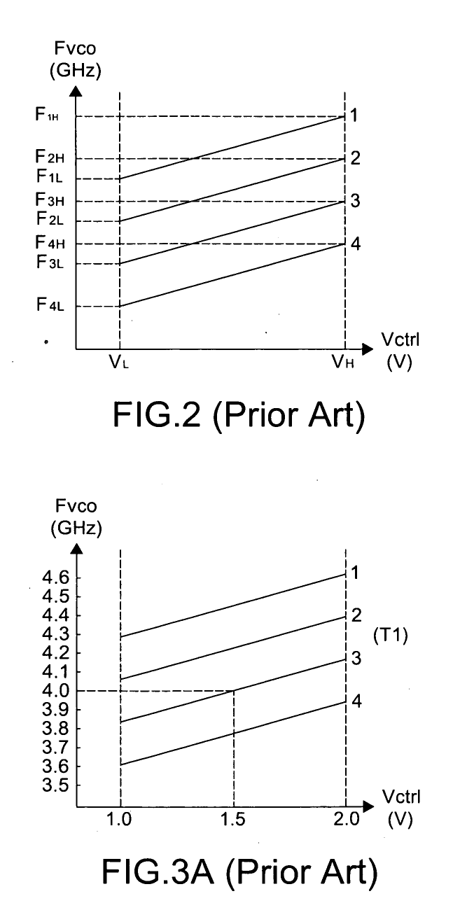

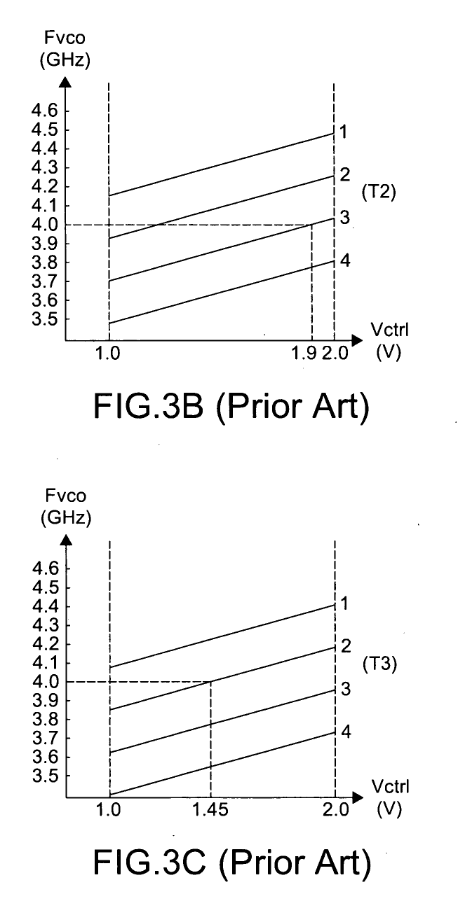

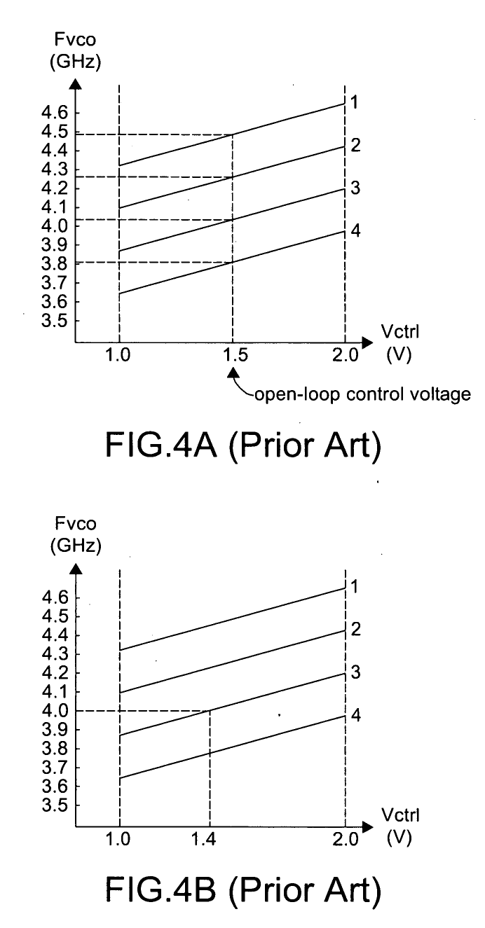

### DETAILED DESCRIPTION OF THE PREFERRED EMBODIMENT

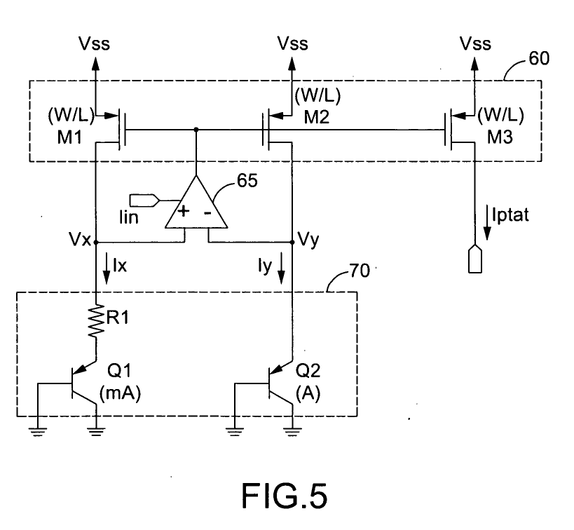

Please refer to FIG. 5 showing a schematic diagram of a PTAT current generating circuit comprising PMOS field effect transistors (FET), PNP bipolar transistors and an operational amplifier. The PTAT current generating circuit comprises a mirroring circuit 60, an operational amplifier 65 and an input circuit 70. The mirroring circuit 60 comprises three PMOS FETs M1, M2 and M3. For example, M1, M2 and M3 have a same width-length (W/L) ratio. Further, M1, M2 and M3 have their gates connected to one another, sources connected to a power supply Vss, and drains for outputting currents Ix, Iy and Iptat respectively. The operational amplifier 65 has its output end connected to the gates of M1 and M2, positive input end connected to the drain of Ml, and negative input end connected to the drain of M2.

The input circuit 70 comprises a first resistor R1 and two bipolar transistors Q1 and Q2. Q1 has an area of m times that of Q2. Both Q1 and Q2 have their bases and collectors connected to ground to form a diode connection. Q2 has its emitter connected to the negative input end of the operational amplifier 65, while Q1 has its emitter connected to the first resistor R1 further connected to the positive input end of the operational amplifier 65. It should be noted that the input circuit 70 may also be realized using FETs in conjunction with resistors.

As observed from the PTAT current generating circuit in FIG. 5, for that M1, M2 and M3 have the same W/L ratio, the respective output currents Iptat, Iy and Ix from the drains of M3, M2 and M1 are the same. That is,

Iₓ=I_{y}=Iₚₜₐₜ (1)

Since the operational amplifier 65 has infinite gain, a negative input end voltage Vy and a positive input end voltage Vx of the operational amplifier 65 are equal. Therefore,

R_{I}Iₓ+V_{EB1}=V_{EB2} (2)

Further, Q1 and Q2 form a diode connection and Q1 has an area of m times of that of Q2. Hence,

$${I}_{x} = {mI}_{s} {e}^{\frac{{V}_{EB 1}}{{V}_{T}}}$$

$$and$$

$${I}_{y} = {I}_{s} {e}^{\frac{{V}_{EB 2}}{{V}_{T}}} .$$

It is then inferred that,

V_{BE1}=V_{T} 1n(Iₓ/mIₛ) (3)

V_{BE2}=V_{T} 1n(I_{y}/Iₛ) (4)

wherein, Iₛ is a saturation current and V_{T} is a thermal voltage of Q1.

By combining equations (1), (2), (3) and (4), it is concluded that,

Iₚₜₐₜ=(1/R₁)V_{T} 1n m (5)

From equation (5), the PTAT current Iptat varies only along with temperature change for that the thermal voltage V_{T} varies along with temperature change. More specifically, the amplitude of the PTAT current Iptat may be regarded as a temperature signal for deducing the operating temperature of a circuit. Alternatively, the PTAT current Iptat may flow through a resistor; and the operating temperature of a circuit may also be obtained according to the amplitude of the voltage across the resistor.

Therefore, the band selecting method according to the invention uses a temperature signal outputted by a temperature detecting circuit, e.g., a PTAT current generating circuit, for performing band selection of a VCO.

According to one embodiment of the invention, an open-loop control voltage is determined by a temperature signal provided by a temperature detecting circuit. When a PLL performs coarse band selection, an ambient temperature of the PLL is obtained utilizing the temperature signal, and the open-loop control voltage is determined based on the temperature variance trend during operations of the PLL.

For example, suppose the PLL performs coarse selection at a low temperature. The temperature increases when operating the PLL at the low temperature. Preferably, the open-loop control voltage selects a voltage near V_{L} in the linear control range. Thus, as the PLL is closed, the range that the control voltage V_{ctrl} increases within the linear control range expands.

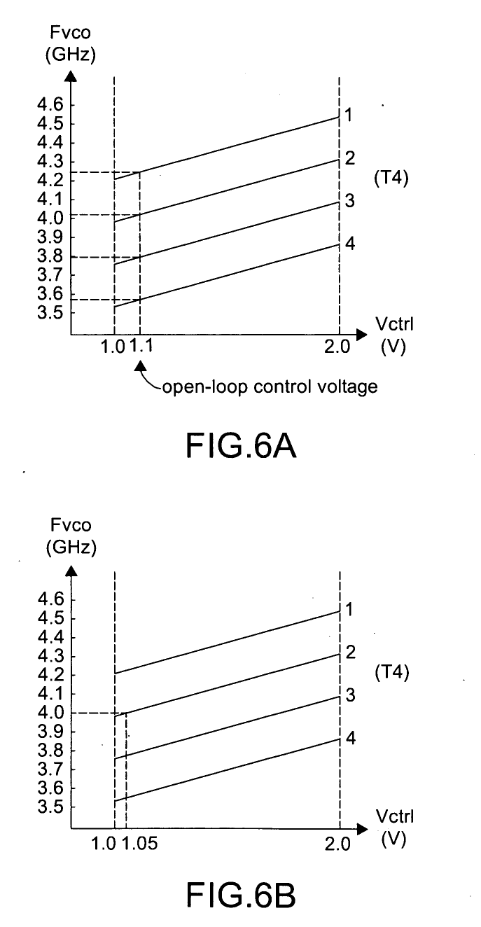

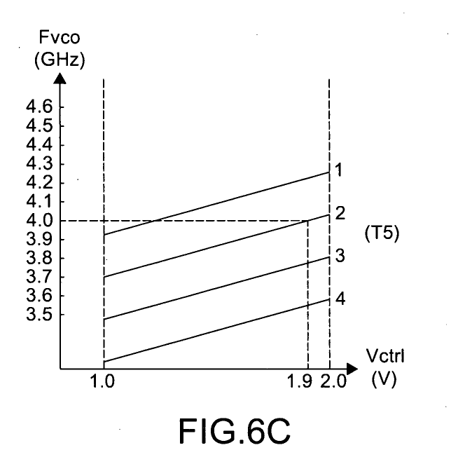

Please refer to FIG. 6A showing an open-loop coarse selection according to one embodiment of the invention. Suppose the VCO has four bands 1, 2, 3 and 4, V_{L}=1V and V_{H}=2V, F_{ref} is 40 MHz, and N of the frequency divider 45 is 100. Further, suppose a current temperature of a low temperature at T4, e.g., below 10° C., is obtained according to the temperature signal during open-loop coarse selection, a voltage value at the linear control range boundary near V_{L} is selected as the open-loop control voltage, such as 1.1V.

With reference to FIG. 6A, four situations of four bands when the PLL is open shall be discussed below. In a first situation, after selecting the first band (1) of the VCO and inputting the open-loop control voltage, a first voltage controlled output signal in a first voltage controlled frequency F_{vco1} of 4.25 GHz is generated, and a first divided frequency F_{D1} of the first frequency divided signal is detected to be 42.5 MHz. In a second situation, after selecting the second band (2) of the VCO and inputting the open-loop control voltage, a second voltage controlled output signal in a second voltage controlled frequency F_{vco2} of 4.01 GHz is generated, and a second divided frequency F_{D2} of the second frequency divided signal is detected to be 40.1 MHz. In a third situation, after selecting the third band (3) of the VCO and inputting the open-loop control voltage, a third voltage controlled output signal in a third voltage controlled frequency F_{vco3} of 3.80 GHz is generated, and a third divided frequency F_{D3} of the third frequency divided signal is detected to be 38.0 MHz. In a fourth situation, after selecting the fourth band (4) of the VCO and inputting the open-loop control voltage, a fourth voltage controlled output signal in a fourth voltage controlled frequency F_{vco4} of 3.59 GHz is generated, and a first divided frequency F_{D4} of the fourth frequency divided signal is detected to be 35.9 MHz.

Note that the second divided frequency F_{D2} of the second frequency divided signal is 40.1 MHz, which is the closest to 40 MHz of the reference frequency F_{ref}. Therefore, the PLL coarsely selects the second band (2) of the VCO for operations. Further, as shown in FIG. 6B, when the PLL is closed for that connection between the loop filter 30 and the VCO 40, the second band (2) becomes the operating band and the control voltage V_{ctrl} automatically adjusts to 1.05V such that the PLL steadily outputs a voltage controlled frequency F_{vco} in 4GHz.

During normal operations of the PLL, when the temperature increases from the low temperature of T4, the control voltage V_{ctrl} gradually increases from 1.05V to allow the PLL accurately outputting the F_{vco} of 4 GHz. In this embodiment, since the open-loop coarse selection selects an open-loop control voltage that is close to V_{L}, the increasing control voltage V_{ctrl} at this point is 0.95V away from the other boundary V_{H}. That is to say, it is unlikely that the control voltage V_{ctrl} exceeds the linear control range. Referring to FIG. 6C, when the temperature of the PLL increases from T4 to T5, e.g., 125° C., the V_{ctrl} of the VCO remains in the linear control range and the PLL does not become unlocked.

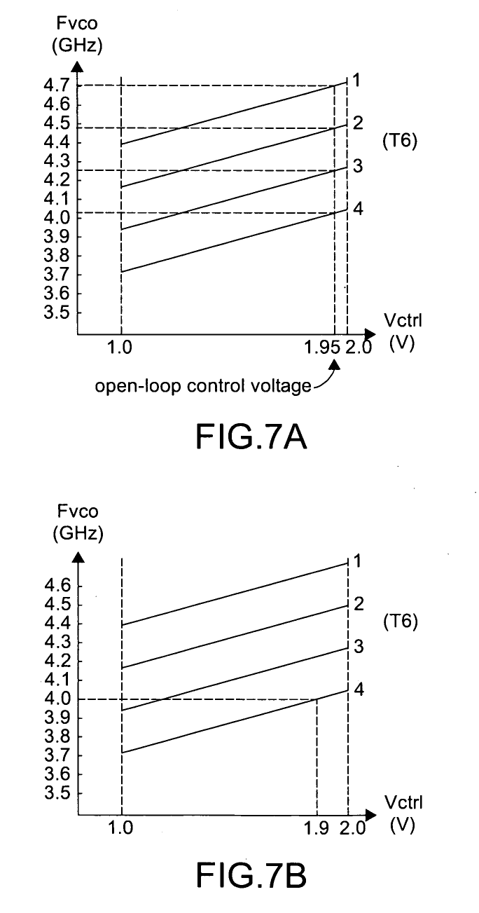

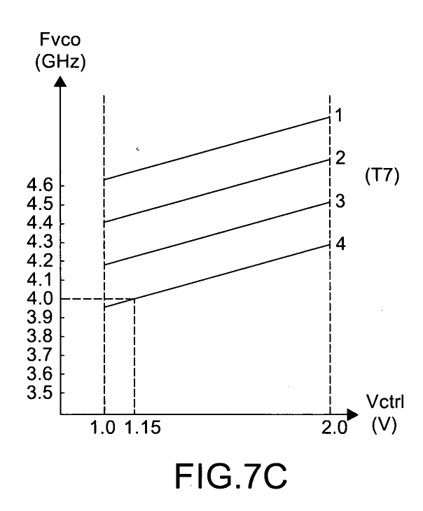

Referring to FIG. 7A showing open-loop coarse selection according to one embodiment of the present invention. Suppose the VCO has four bands 1, 2, 3 and 4, V_{L}=1V and V_{H}=2V, F_{ref} is 40 MHz, and N of the frequency divider 45 is 100. Further, suppose a current temperature of a high temperature at T6, e.g., above 125° C., is obtained according to the temperature signal during open-loop coarse selection, a voltage value at the linear control range boundary near V_{H} is selected as the open-loop control voltage, such as 1.95V.

With reference to FIG. 7A, four situations of operating at the four bands when the PLL is open shall be discussed below. In a first situation, after selecting the first band (1) of the VCO and inputting the open-loop control voltage, a first voltage controlled output signal in a first voltage controlled frequency F_{vco1} of 4.70 GHz is generated, and a first divided frequency F_{D1} of the first frequency divided signal is detected to be 47.0 MHz. In a second situation, after selecting the second band (2) of the VCO and inputting the open-loop control voltage, a second voltage controlled output signal in a second voltage controlled frequency F_{vco2} of 4.48 GHz is generated, and a second divided frequency F_{D2} of the second frequency divided signal is detected to be 44.8 MHz. In a third situation, after selecting the third band (3) of the VCO and inputting the open-loop control voltage, a third voltage controlled output signal in a third voltage controlled frequency F_{vco3} of 4.25 GHz is generated, and a third divided frequency F_{D3} of the third frequency divided signal is detected to be 42.5 MHz. In a fourth situation, after selecting the fourth band (4) of the VCO and inputting the open-loop control voltage, a fourth voltage controlled output signal in a fourth voltage controlled frequency F_{vco4} of 4.04 GHz is generated, and a fourth divided frequency F_{D4} of the first frequency divided signal is detected to be 40.4 MHz.

Note that the fourth divided frequency F_{D4} of the fourth frequency divided signal is 40.4 MHz, which is the closest to 40 MHz of the reference frequency F_{ref}. Therefore, the PLL coarsely selects the fourth band (4) of the VCO for operations. As shown in FIG. 7B, when the PLL is closed for that connection between the loop filter 30 and the VCO 40 is closed, the fourth band (4) becomes the operating band and the control voltage V_{ctrl} automatically adjusts to 1.9V such that the PLL accurately outputs a voltage controlled frequency F_{vco} in 4 GHz.

During normal operations of the PLL, when the temperature decreases from the high temperature of T6, the control voltage V_{ctrl} gradually decreases from 1.9V to allow the PLL accurately outputting the F_{vco} of 4 GHz. In this embodiment, since the open-loop coarse selection selects an open-loop control voltage that is close to V_{H}, the decreasing control voltage V_{ctrl} at this point is 0.9V away from the other boundary V_{L}. That is to say, it is unlikely that the control voltage V_{ctrl} exceeds the linear control range. Referring to FIG. 7C, when the temperature of the PLL decreases from T6 to T7, e.g., 10° C., the V_{ctrl} of the VCO remains in the linear control range and the PLL does not become unlocked.

Therefore, an advantage of the present invention lies in that, the open-loop control voltage is determined according to a temperature signal provided by the temperature detecting circuit when the PLL performs coarse band selection in an open-loop. Further, when band selection of the VCO is completed, the control voltage V_{ctrl} is unlikely to exceed the linear control range and chances that the PLL become unlocked therefor are minimized.

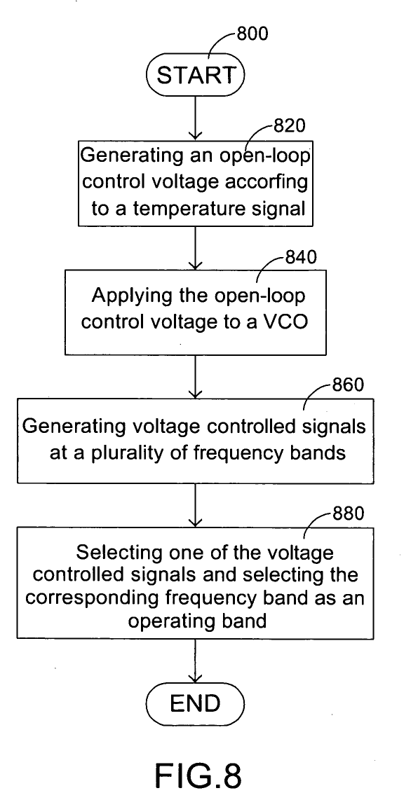

FIG. 8 shows a flowchart of a band selecting method applied to a VCO of a PLL when the PLL is open according to one preferred embodiment of the invention. The method starts with Step 800. In Step 820, an open-loop control voltage located within a linear control range is generated according to a temperature signal. For example, the temperature signal is a current signal generated by a PTAT current generating circuit. Alternatively, the open-loop control signal is a voltage generated by flowing a PTAT current through a resistor. In Step 840, the open-loop control voltage is applied to a VCO. In step 860, the VCO generates a plurality of voltage controlled signals at a plurality of frequency bands. For example, the VCO sequentially switches among the bands such that the VCO sequentially generates the voltage controlled signals for each band, each of which having a voltage controlled frequency. In Step 880, one of the voltage controlled signals is selected and its corresponding frequency band is selected as an operating band of the PLL for the PLL in a closed-loop. For example, the voltage controlled signals are in turn inputted into and divided by a frequency divider to generate frequency divided signals. The frequency divided signals are compared with a reference signal to select a best frequency divided signal therefrom. The frequency of the best frequency divided signal is the closest to the reference frequency of the reference signal, and the voltage controlled signal corresponding to the best frequency divided signal is the selected voltage controlled signal.

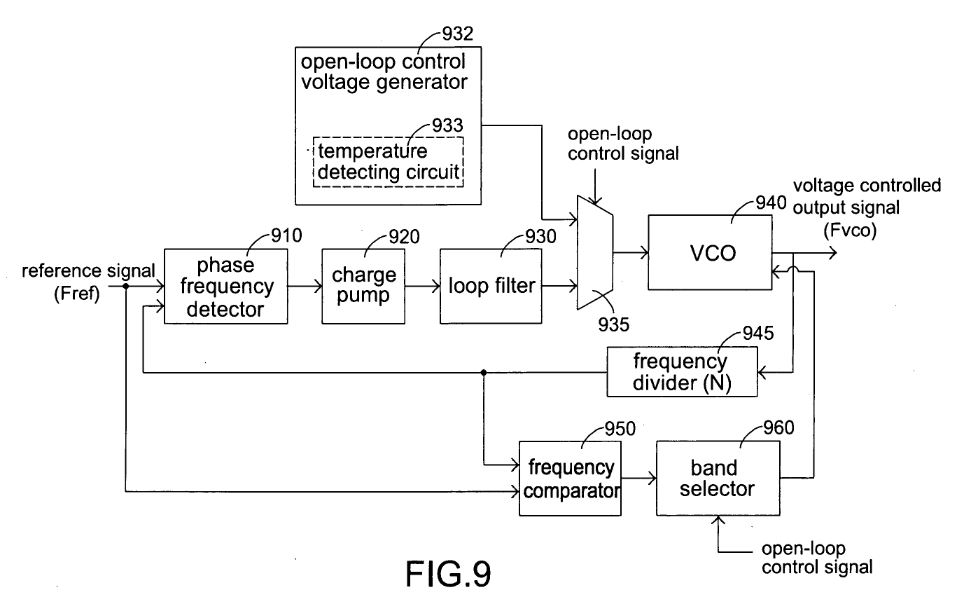

Referring to FIG. 9 showing a PLL according to one preferred embodiment of the invention, the PLL comprises a phase frequency detector 910, a charge pump 920, a loop filter 930, a VCO 940, a frequency divider 945, a multiplexer 935, an open-loop control voltage generator 932, a frequency comparator 950 and a band selector 960.

According to an open-loop control signal, the multiplexer 935 inputs the control voltage V_{ctrl} generated by the loop filter 930 or the open-loop control voltage generator 932 into the VCO 940. The multiplexer 935 may be a selector such as a switch element. The frequency comparator 950 receives a frequency divided signal and a reference signal to generate a frequency difference signal to the band selector 960. When the open-loop control signal is asserted, the band selector 960 switches between a plurality of bands of the VCO 940, so that the band selector 960, according to a plurality of frequency difference signals from the frequency comparator 950, selects a preferred band of the VCO 940 to provide the selected band to be applied to a closed PLL.

When the PLL is open, an open-loop control signal is asserted. Thus, the multiplexer 935 outputs the control voltage V_{ctrl} generated by the open-loop control voltage generator 932. The open-loop control voltage generator 932 further comprises a temperature detecting circuit 933, e.g., a PTAT current generating circuit, such that the control voltage V_{ctrl} generating by the open-loop control voltage generator 932 is associated with a temperature signal provide by the temperature detecting circuit 933. For example, a PTAT current flows through a resistor to generate a voltage that is applied as the control voltage V_{ctrl}. According to the open-loop control signal, the band selector 960 controls the VCO 940 to switch between the bands of the VCO 940. Preferably, based on a plurality of frequency difference signals, the band selector 960 selects a preferred band of the VCO 940, such as a band having the smallest frequency difference.

When the PLL is closed, a closed-loop control signal is asserted. For having already selected a frequency band, the VCO 940 generates the voltage controlled output signal according to the selected frequency band and the control voltage V_{ctrl} from the loop filter 930. In this embodiment, the control voltage V_{ctrl} is unlikely to exceed the linear control range since the ambient temperature changes are taken into consideration by the open-loop control voltage generator 932. Therefore, chances that the PLL become unlocked are lowered to significantly increase reliability of the PLL.

According to the present invention, a PLL comprises a loop filter, for outputting a first control voltage; an open-loop control voltage generator, for outputting a second control voltage associated with an ambient temperature; a selector, e.g., a multiplexer or a switch, for selecting either the first control voltage or the second control voltage as a third control voltage according to an open-loop control signal; a VCO, for generating a voltage controlled output signal according to the third control voltage; a frequency divider, for receiving the voltage controlled output signal and dividing the same to generate a frequency divided signal; a phase frequency detector, for generating a phase difference signal according to the frequency divided signal and a reference signal; a charge pump, for generating an output current to the loop filter according to the phase difference signal to generate the first control voltage; a frequency comparator, for generating a frequency difference signal according to the frequency divided signal and the reference signal; and a band selector, for switching between a plurality of frequency bands of the VCO when an open-loop control signal is asserted to further select an operating band from the bands of the VCO according to a plurality of frequency difference signals outputted by the frequency comparator, and for controlling the VCO when the open-loop control signal is deasserted to generate the voltage controlled output signal according to the operating band and the third control voltage. For example, the open-loop control voltage generator comprises a temperature detecting circuit for providing a temperature signal to associate the second control voltage with the temperature signal. Alternatively, the temperature detecting circuit is a PTAT current generating circuit, and the temperature signal is a current signal generated by the PTAT current generating circuit. Alternatively, the temperature detecting circuit is a PTAT current generating circuit, and the temperature signal is generated by flowing a PTAT current through a resistor. While the invention has been described in terms of what is presently considered to be the most practical and preferred embodiments, it is to be understood that the invention needs not to be limited to the above embodiments. On the contrary, it is intended to cover various modifications and similar arrangements included within the spirit and scope of the appended claims which are to be accorded with the broadest interpretation so as to encompass all such modifications and similar structures.

What is claimed is:

1. A band selecting method for use in a voltage controlled oscillator (VCO) of a phase locked loop (PLL), comprising steps of:
generating an open-loop control voltage according to a temperature signal;
applying the open-loop control voltage to the VCO;
generating a plurality of voltage controlled signals corresponding to a plurality of bands of the VCO; and
selecting one of the plurality of bands and the corresponding voltage control signal as an initial band so as to provide for the PLL in a closed-loop.

2. The band selecting method as claimed in claim 1, wherein the step of generating the voltage controlled signals is switching sequentially among the bands, such that the VCO sequentially generates the voltage controlled signals, each of which having a voltage controlled frequency.

3. The band selecting method as claimed in claim 1, wherein the selecting step further comprises:
inputting the voltage controlled signals into a frequency divider for dividing frequency to generate a plurality of frequency divided signals;
comparing the frequency divided signals with a reference signal to select one of the of the frequency divided signals, wherein the selected frequency divided signal's frequency is closest to the reference signal's frequency; and
selecting one of the plurality of voltage controlled signals wherein the selected voltage controlled signal corresponding to the selected frequency divided signal.

4. The band selecting method as claimed in claim 1, wherein the temperature signal is a current signal generated by a
proportional-to-absolute-temperature (PTAT) current generating circuit.

5. The band selecting method as claimed in claim 1, wherein the temperature signal is generated by flowing a proportional-to-absolute-temperature (PTAT) current through a resistor.

6. The band selecting method as claimed in claim 1, wherein the open-loop control voltage is within a linear control range.

7. The band selecting method as claimed in claim 6, wherein when a temperature indicated by the temperature signal is determined at a high temperature range or a low temperature range, the open-loop control voltage is near a boundary of the linear control range.

8. A phase locked loop (PLL), comprising:
a loop filter, for outputting a first control voltage;
an open-loop control voltage generator, for outputting a second control voltage associated with an ambient temperature;
a selector, for selecting either the first control voltage or the second control voltage to output as a third control voltage according to an open-loop control signal;
a VCO, for generating a voltage controlled signal according to the third control voltage;
a frequency divider, for generating a frequency divided signal according to the voltage controlled signal;
a phase frequency detector, for generating a phase difference signal according to the frequency divided signal and a reference signal; and
a charge pump, for generating an output current to the loop filter according to the phase difference signal wherein the loop filter generates the first control voltage accordingly.

9. The PLL as claimed in claim 8, further comprising:
a frequency comparator, for generating a frequency difference signal according to the frequency divided signal and the reference signal; and
a band selector, for switching between a plurality of bands of the VCO when the open-loop control signal is asserted, and for selecting an operating band among the bands of the VCO according to a plurality of frequency difference signals outputted from the frequency comparator; and, when the open-loop control signal is deasserted, controlling the VCO to generate the voltage controlled signal according to the operating band and the third control voltage.

10. The PLL as claimed in claim 9, wherein the third control voltage is within a linear control range of the operating band.

11. The PLL as claimed in claim 9, wherein each of the bands has a linear control range, and the second control voltage is near a boundary of the linear control range when the ambient temperature indicated by the temperature signal is at a high temperature range or a low temperature range.

12. The PLL as claimed in claim 8, wherein the selector is a multiplexer.

13. The PLL as claimed in claim 8, wherein the selector is a switch.

14. The PLL as claimed in claim 8, wherein the open-loop control voltage generator comprises a temperature detecting circuit for providing a temperature signal to associate the second control voltage with the temperature signal.

15. The PLL as claimed in claim 14, wherein the temperature detecting circuit is a current signal generated by a proportional-to-absolute-temperature (PTAT) current generating circuit.

16. The PLL as claimed in claim 14, wherein the temperature signal is generated by a proportional-to-absolute-temperature (PTAT) current flowing through a resistor.
